(19) United States
(12) Patent Application Publication
(10) Pub. No.: US 2026/0122879 A1
(43) Pub. Date: Apr. 30, 2026

(54) SEMICONDUCTOR DEDVICE AND METHOD FOR FABRICATING THE SAME

(71) Applicant: SK hynix Inc., Gyeonggi-do (KR)

(72) Inventor: Se Hyun KIM, Gyeonggi-do (KR)

(21) Appl. No.: 19/346,562

(22) Filed: Oct. 1, 2025

(30) Foreign Application Priority Data
Oct. 31, 2024 (KR) 10-2024-0152857

(51) Int. Cl. H10B 12/00

(52) U.S. Cl. CPC H10B 12/315; H10B 12/05

(57) ABSTRACT

Disclosed is a semiconductor device which includes a bit line extending in a first direction; a first gate extending in a second direction perpendicular to the first direction; a second gate extending parallel to the first gate; an active region including a vertical portion located between the first gate and the second gate, and a horizontal portion in contact with the bit line and the vertical portion; and a first gate insulating layer disposed between the first gate and the vertical portion. The first gate insulating layer includes a lower gate insulating layer in contact with the first gate and an upper gate insulating layer in contact with the vertical portion. The upper gate insulating layer has a higher dielectric constant than the lower gate insulating layer.

### CROSS-REFERENCE TO RELATED APPLICATIONS

This application claims the benefit of priority to Korean Patent Application No. 10-2024-0152857, filed on Oct. 31, 2024, the entire contents of which are incorporated herein by reference.

### TECHNICAL FIELD

The present disclosure relates to a semiconductor device, and more particularly, relates to a semiconductor device including memory cells.

### BACKGROUND

As compactness of semiconductor devices and an improvement in the degree of integration thereof are emerging as a major issue, memory cells included in the semiconductor devices may be formed to have a three-dimensional pattern. The compact memory cells having the three-dimensional pattern may include components for improving the operating characteristics of the memory cells.

### SUMMARY

The present disclosure has been made to solve the above-mentioned concerns occurring in the prior art while maintaining intact advantages achieved by the prior art.

An aspect of the present disclosure provides a semiconductor device with improved integration.

Another aspect of the present disclosure provides a semiconductor device with improved leakage current characteristics.

The technical concerns to be solved by the present disclosure are not limited to the aforementioned concerns, and any other technical concerns not mentioned herein will be clearly understood from the following description by those skilled in the art to which the present disclosure pertains.

According to an aspect of the present disclosure, a semiconductor device includes a bit line extending in a first direction; a first gate extending in a second direction perpendicular to the first direction; a second gate extending parallel to the first gate; an active region including a vertical portion located between the first gate and the second gate, and a horizontal portion in contact with the bit line and the vertical portion; and a first gate insulating layer disposed between the first gate and the vertical portion. The first gate insulating layer includes a lower gate insulating layer in contact with the first gate and an upper gate insulating layer in contact with the vertical portion. The upper gate insulating layer has a higher dielectric constant than the lower gate insulating layer.

According to an embodiment, the semiconductor device may further include a second gate insulating layer disposed between the second gate and the active region.

According to an embodiment, the active region may include an indium gallium zinc oxide semiconductor and may have a channel region formed therein.

According to an embodiment, the semiconductor device may further include a first contact region located on an opposite side of the vertical portion and a second contact region overlapping the first contact region.

According to an embodiment, the first contact region may include a same material as the active region, and the second contact region may include at least one of metal, metal silicide, or metal nitride.

According to an embodiment, the semiconductor device may further include a capacitor overlapping the second contact region.

According to an embodiment, the first gate may be configured to receive a control signal different from a control signal provided to the second gate.

According to an embodiment, the lower gate insulating layer may include silicon oxide, and the upper gate insulating layer may include at least one of hafnium oxide, zirconium oxide, aluminum oxide, lanthanum oxide, titanium oxide, tantalum oxide, niobium oxide, or strontium titanium oxide.

According to another aspect of the present disclosure, a semiconductor device includes a bit line that extends in a first direction, a first gate that extends in a second direction perpendicular to the first direction, a pair of second gates that are located on opposite sides of the first gate and that extend parallel to the first gate, an active region including a vertical portion located between one of the pair of second gates and the first gate, and a horizontal portion that is in contact with one side of the vertical portion and that extends in the first direction, and a first gate insulating layer disposed between the first gate and the active region. The first gate insulating layer includes a lower gate insulating layer in contact with the first gate and an upper gate insulating layer in contact with the vertical portion. The upper gate insulating layer has a higher dielectric constant than the lower gate insulating layer.

According to another embodiment, the bit line may be in contact with the horizontal portion.

According to another embodiment, the semiconductor device may further include a second gate insulating layer disposed between the second gate and the active region.

According to another embodiment, the active region may include an amorphous indium gallium zinc oxide semiconductor.

According to another embodiment, the semiconductor device may further include a first contact region located on an opposite side of the vertical portion and a second contact region overlapping the first contact region.

According to another embodiment, the first contact region may include a same material as the active region, and the second contact region may include at least one of metal, metal silicide, or metal nitride.

According to another embodiment, the semiconductor device may further include a capacitor overlapping the second contact region.

According to another embodiment, the lower gate insulating layer may include silicon oxide, and the upper gate insulating layer may include at least one of hafnium oxide, zirconium oxide, aluminum oxide, lanthanum oxide, titanium oxide, tantalum oxide, niobium oxide, or strontium titanium oxide.

According to another aspect of the present disclosure, a method for fabricating a semiconductor device includes forming, in a substrate, a bit line that extends in a first direction; forming, on the bit line, a first gate that extends in a second direction perpendicular to the first direction; forming a first gate insulating layer in contact with the first gate, forming an active region including a vertical portion and a horizontal portion, the vertical portion extending along a sidewall of the first gate insulating layer, the horizontal portion being in contact with the bit line; forming a second gate insulating layer in contact with the active region; and forming a second gate in contact with the second gate insulating layer. The forming of the first gate insulating layer includes forming a lower gate insulating layer in contact with the first gate and forming an upper gate insulating layer located on the lower gate insulating layer. The upper gate insulating layer has a higher dielectric constant than the lower gate insulating layer.

According to another embodiment, the active region may include an amorphous indium gallium zinc oxide semiconductor.

According to another embodiment, the lower gate insulating layer may include silicon oxide, and the upper gate insulating layer may include at least one of hafnium oxide, zirconium oxide, aluminum oxide, lanthanum oxide, titanium oxide, tantalum oxide, niobium oxide, or strontium titanium oxide.

### BRIEF DESCRIPTION OF THE DRAWINGS

The above and other objects, features and advantages of the present disclosure will be more apparent from the following detailed description taken in conjunction with the accompanying drawings:

FIG. 1 is a schematic perspective view of a semiconductor device according to an embodiment of the present disclosure;

FIG. 2A is a sectional view obtained by cutting the center of a first gate along a cutting line parallel to a second direction according to an embodiment of the present disclosure;

FIG. 2B is a sectional view obtained by cutting the center of a second gate along a cutting line parallel to the second direction according to an embodiment of the present disclosure;

FIG. 2C is a sectional view obtained by cutting the center of a bit line along a cutting line parallel to a first direction according to an embodiment of the present disclosure;

FIGS. 3A to 3C are views for explaining a method for forming a bit line included in the semiconductor device according to an embodiment of the present disclosure;

FIGS. 4A to 4C are views for explaining a method for forming the first gate included in the semiconductor device according to an embodiment of the present disclosure;

FIGS. 5A to 5C and FIGS. 6A to 6C are views for explaining a method for forming a lower gate insulating layer included in the semiconductor device according to an embodiment of the present disclosure;

FIGS. 7A to 7C and FIGS. 8A to 8C are views for explaining a method for forming an upper gate insulating layer included in the semiconductor device according to an embodiment of the present disclosure;

FIGS. 9A to 9C are views for explaining a method for forming an active region included in the semiconductor device according to an embodiment of the present disclosure;

FIGS. 10A to 10C are views for explaining a method for forming a second gate insulating layer included in the semiconductor device according to an embodiment of the present disclosure;

FIGS. 11A to 11C are views for explaining a method for forming the second gate included in the semiconductor device according to an embodiment of the present disclosure; and

FIGS. 12A to 12C and FIGS. 13A to 13C are views for explaining a method for forming a capacitor included in the semiconductor device according to an embodiment of the present disclosure.

### DETAILED DESCRIPTION

Hereinafter, various embodiments of the present disclosure will be described with reference to the accompanying drawings. The above and other aspects, features, and advantages of the present disclosure will become apparent from the following description of embodiments given in conjunction with the accompanying drawings. However, this is not intended to limit the present disclosure to particular embodiments.

The present disclosure is not limited to the embodiments disclosed herein and may be implemented in various different forms. Those skilled in the art to which the present disclosure pertains will recognize that modification, equivalent, and/or alternative on the various embodiments described herein can be variously made without departing from the scope and spirit of the present disclosure.

In adding the reference numerals to the components of each drawing, it should be noted that the identical components are designated by the identical reference numerals even when they are displayed on other drawings.

In describing the embodiments of the present disclosure, a detailed description of well-known features or functions will be ruled out in order not to unnecessarily obscure the gist of the present disclosure.

As used herein, the singular forms are intended to include the plural forms as well, unless context clearly indicates otherwise. It will be further understood that the terms “comprise” and/or “comprising”, when used in this specification, specify the presence of stated components, steps, operations, and/or elements, but do not preclude the presence or addition of one or more other components, steps, operations, and/or elements.

Hereinafter, a semiconductor device and a method for fabricating the same according to embodiments of the present disclosure will be described with reference to the accompanying drawings.

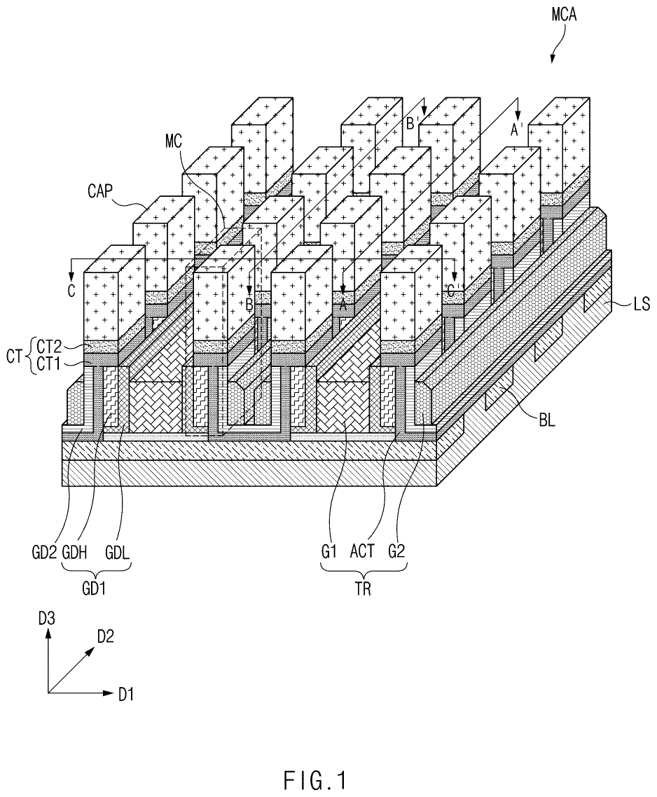

FIG. 1 is a schematic perspective view of a semiconductor device according to an embodiment of the present disclosure.

Referring to FIG. 1, the semiconductor device may include a substrate LS and a memory cell array MCA formed on the substrate LS. The memory cell array MCA may include a plurality of memory cells MC repeatedly arranged on the substrate LS.

According to an embodiment, each of the memory cells MC may have a three-dimensional structure.

More specifically, each of the memory cells MC included in the memory cell array MCA may include a bit line BL, a transistor TR, and a capacitor CAP.

The bit line BL may be located inside the substrate LS and may extend in a first direction D1 parallel to one surface of the substrate LS. Adjacent bit lines BL may be separated from each other by a bit line separation layer (not illustrated).

The bit line separation layer may include, for example, silicon oxide, silicon nitride, or a combination thereof.

The capacitor CAP may be spaced apart from the bit line BL in a third direction D3. The capacitors CAP may be arranged in a matrix form or obliquely with respect to the regions where gates G1 and G2 and the bit lines BL overlap.

The capacitor CAP may be disposed to overlap the central portions of a first contact region CT1 and a second contact region CT2 in contact with one side of an active region ACT.

The first contact region CT1 and the second contact region CT2 may constitute one contact region CT.

The transistor TR may be located between the capacitor CAP and the bit line BL.

The transistor TR may include at least a portion of the active region ACT connected with the bit line BL and may include the first gate G1 and the second gate G2. In addition, the transistor TR may include a first gate insulating layer GD1 located between the first gate G1 and a vertical portion of the active region ACT adjacent thereto and a second gate insulating layer GD2 located between the second gate G2 and the vertical portion of the active region ACT adjacent thereto. According to an embodiment, the first gate insulating layer GD1 may include a plurality of insulating layers having different dielectric constants. For example, the first gate insulating layer GD1 may include a lower gate insulating layer GDL in contact with the first gate G1 and an upper gate insulating layer GDH in contact with the active region ACT.

According to an embodiment, the lower gate insulating layer GDL may include silicon oxide. The silicon oxide may have a dielectric constant of about 3.9.

The upper gate insulating layer GDH may include a high-k material having a dielectric constant of 4 or more. For example, the high-k material may have a dielectric constant of about 20 or more.

The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In another embodiment, the upper gate insulating layer GDH may be formed of a composite layer including two or more layers of the high-k material mentioned above.

According to the embodiment of FIG. 1, a word line driving voltage may be provided to the second gate G2 extending in a second direction D2. In other words, the second gate G2 may operate as a word line of the transistor TR.

In this case, a voltage different from the voltage provided to the second gate G2 may be provided to the first gate G1, which extends to face the second gate G2, to block interference between the gates G2 of adjacent transistors TR. For example, a ground voltage may be provided to the first gate G1, and the first gate G1 may operate as a back gate.

The first direction D1 may be a direction perpendicular to the second direction D2, and the third direction D3 may be a direction perpendicular to the first direction D1 and the second direction D2.

Each of the memory cells MC may include the active region ACT located between the capacitor CAP and the bit line BL. The active region ACT may include the first contact region CT1 on one side of the vertical portion, and the second contact region CT2 may be disposed on the first contact region CT1.

The capacitor CAP may be in contact with the active region ACT through the second contact region CT2 and the first contact region CT1.

The active region ACT may include a channel region and source/drain regions of the transistor TR. In other words, the active region ACT may be a region where a channel is formed when the transistor TR operates and may be a region including the source region and the drain region.

Depending on the voltage applied to the second gate G2 of the transistor TR, the channel region may be formed in the active region ACT, and electrons may move between the source/drain regions through the formed channel region.

The active region ACT may include a horizontal portion extending in the first direction D1 and the vertical portion extending in the third direction D3.

Each of the memory cells MC may include one transistor TR.

Two vertical portions included in the active region ACT and adjacent to each other may be connected by one horizontal portion. The horizontal portion of the active region ACT may be connected with the bit line BL.

The active region ACT may be electrically isolated from the gates G1 and G2 by the insulating layers GD1 and GD2.

The memory cell array MCA may include a Dynamic Random Access Memory (DRAM) memory cell array. In another embodiment, the memory cell array MCA may include Phase Change RAM (PCRAM), Paraelectric Random Access Memory (PERAM), or Magnetoresistive Random Access Memory (MRAM) memory cell arrays.

The capacitor CAP may be replaced with a different memory element depending on the type of the memory cell array MCA.

The substrate LS may be a material suitable for semiconductor processing.

The substrate LS may include a semiconductor substrate. The substrate LS may be formed of a semiconductor material containing silicon. The substrate LS may include silicon, single crystal silicon, poly silicon, amorphous silicon, silicon germanium, single crystal silicon germanium, polycrystalline silicon germanium, carbon doped silicon, a combination thereof, or a multiple layers thereof.

The substrate LS may include a different semiconductor material such as germanium. The substrate LS may include a group III/V semiconductor substrate, for example, a compound semiconductor substrate such as GaAs.

The substrate LS may include a silicon on insulator (SOI) substrate. In another embodiment, the substrate LS may include a peripheral circuit region (not illustrated) in the lower portion thereof. The peripheral circuit region may include a plurality of control circuits for controlling the memory cell array MCA. At least one control circuit of the peripheral circuit region may include an N-channel transistor, a P-channel transistor, a CMOS circuit, or a combination thereof. At least one control circuit of the peripheral circuit region may include an address decoder circuit, a read circuit, and a write circuit.

The bit line BL may be referred to as a laterally-oriented bit line or a laterally-extended bit line.

The bit line BL may include a conductive material. The bit line BL may include a silicon-base material, a metal-base material, or a combination thereof. The bit line BL may include poly silicon, metal, metal nitride, metal silicide, or a combination thereof.

The bit line BL may include poly silicon, titanium nitride, tungsten (W), or a combination thereof. For example, the bit line BL may include poly silicon or titanium nitride (TiN) doped with an N-type impurity.

The bit line BL may include a stack (TiN/W) of titanium nitride (TiN) and tungsten (W). The bit line BL may further include ohmic contact such as metal silicide.

The memory cells MC horizontally arranged in the first direction D1 may share one bit line BL. The bit line separation layer extending in the first direction D1 may be provided between the adjacent bit lines BL. The bit line separation layer may be constituted by a plurality of layers and may function as a spacer that spaces the adjacent bit lines BL apart from each other.

The gates G1 and G2 may include a metal, a metal mixture, a metal alloy, titanium nitride, tungsten, poly silicon, or a combination thereof.

For example, the gates G1 and G2 may include a TiN/W stack in which titanium nitride and tungsten are sequentially stacked.

The gates G1 and G2 and the bit line BL may extend in directions crossing each other. The active region ACT may include a semiconductor material or an oxide semiconductor material.

The bit line BL may be electrically isolated from the gates G1 and G2 by the bit line separation layer. In other words, the bit line separation layer may be located between the bit line BL and the gates G1 and G2.

The active region ACT may include a plurality of impurity regions. The impurity regions may include the source/drain regions of the transistor TR.

The active region ACT may include doped poly silicon, undoped poly silicon, amorphous silicon, amorphous indium gallium zinc oxide (IGZO) semiconductor, indium zinc oxide (IZO), indium tin oxide (ITO), and indium oxide (InO₃).

The horizontal portion included in the active region ACT may be electrically connected with the bit line BL. In addition, the first contact region CT1 may be in contact with the vertical portion included in the active region ACT, and the capacitor CAP and the active region ACT may be electrically connected through the first contact region CT1 and the second contact region CT2.

The active region ACT may be electrically isolated from the gates G1 and G2 by the gate insulating layers GD1 and GD2. In other words, the gate insulating layers GD1 and GD2 may be disposed between the active region ACT and the gates G1 and G2 to prevent the active region ACT and the gates G1 and G2 from being electrically connected.

In addition, an additional insulating layer (not illustrated) may be disposed between the second gates G2, and the second gates G2 may be electrically isolated from each other by the additional insulating layer (not illustrated).

An insulating layer may have different compositions depending on its location. For example, the insulating layer located between the second gates G2 may include silicon oxide or silicon nitride, and the first gate insulating layer GD1 located between the gates G1 and G2 and the active region ACT may include a high-k material.

The second gate insulating layer GD2 located between the second gate G2 and the active region ACT may include silicon oxide or silicon nitride.

The capacitor CAP may have a shape vertically extending from one surface of the substrate LS and may be disposed in contact with the vertical portion included in the active region ACT. The capacitor CAP may include, for example, a capacitor having a metal-insulator-metal (MIM) structure.

The capacitor CAP may have a three-dimensional structure. The capacitor CAP having the three-dimensional structure may be repeatedly disposed in a matrix form with respect to one surface of the substrate LS. The three-dimensional structure may be, for example, a cylinder shape, a pillar shape, or a pylinder shape. Here, the pylinder shape may refer to a structure in which a pillar shape and a cylinder shape are merged.

According to another embodiment, the capacitor CAP may have a structure obliquely arranged with respect to the second contact region CT2 located in the region where the bit line BL and the gates G1 and G2 overlap, such that the largest number of capacitors are disposed in the same area.

Each of the memory cells MC may share the first gate G1 and the second gate G2. The first gate G1 and the second gate G2 may include the same conductive material.

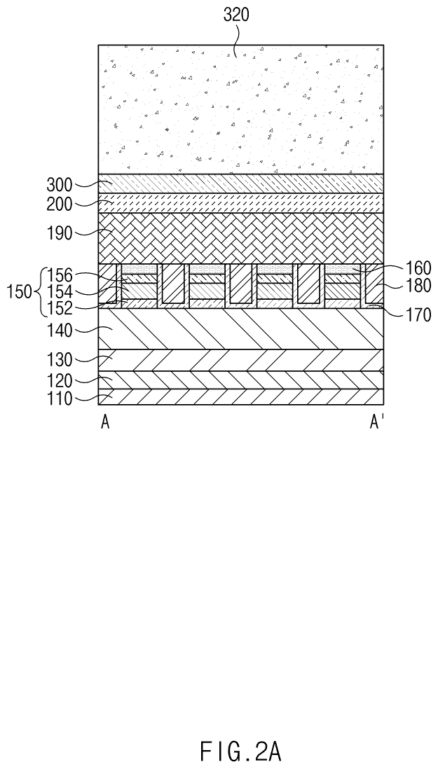

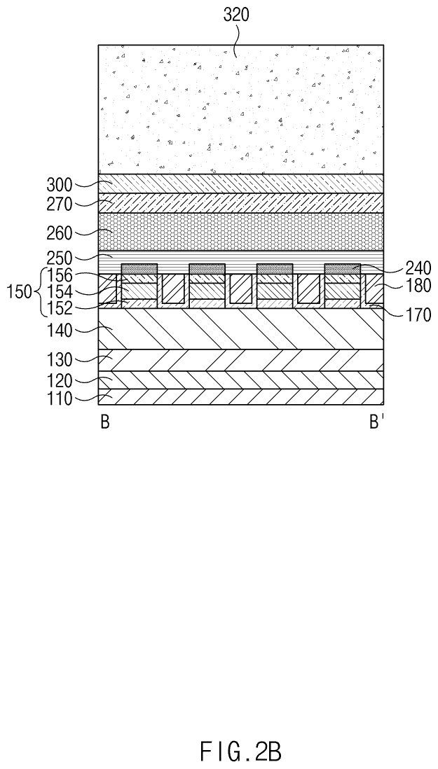

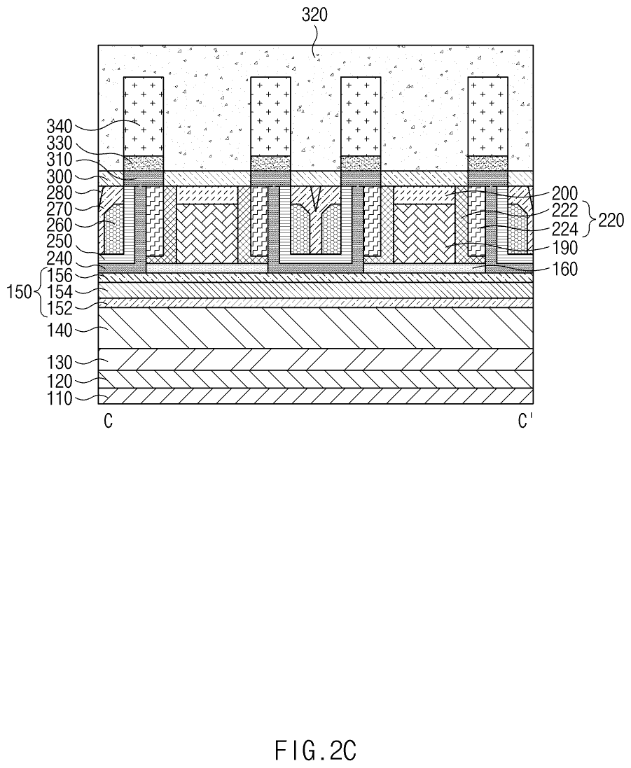

FIG. 2A is a sectional view obtained by cutting the center of the first gate along a cutting line (line A-A′ of FIG. 1) parallel to the second direction according to an embodiment of the present disclosure.

FIG. 2B is a sectional view obtained by cutting the center of the second gate along a cutting line (line B-B′ of FIG. 1) parallel to the second direction according to an embodiment of the present disclosure.

FIG. 2C is a sectional view obtained by cutting the center of the bit line along a cutting line (line C-C′ of FIG. 1) parallel to the first direction according to an embodiment of the present disclosure.

Referring to FIGS. 2A, 2B, and 2C, a substrate layer 110, a silicide layer 120 formed on the substrate layer 110, and a first nitride layer 130 located on the silicide layer 120 are illustrated.

The substrate layer 110 may include a silicon semiconductor material, for example, silicon, single crystal silicon, poly silicon, amorphous silicon, silicon germanium, single crystal silicon germanium, polycrystalline silicon germanium, or carbon-doped silicon.

The substrate layer 110 may include a plurality of control circuits that control operation of the semiconductor device, and the region where the control circuits are provided may be referred to as the peripheral circuit region.

The silicide layer 120 located on the substrate layer 110 may include a metal silicide material such as cobalt silicide (CoSi). Since the silicide layer 120 is provided, the operation resistance of the semiconductor device may be decreased. In addition, the silicide layer 120 may serve as a protective layer for the substrate layer 110 to prevent damage to the substrate layer 110 due to a semiconductor fabricating process.

The first nitride layer 130 located on the silicide layer 120 may be a layer including silicon nitride. Since the first nitride layer 130 includes the silicon nitride, damage to the substrate layer 110 in a high-temperature semiconductor fabricating process may be prevented.

A first oxide layer 140 may be disposed on the first nitride layer 130. The first oxide layer 140 may be a layer including silicon oxide.

Since the first nitride layer 130 and the first oxide layer 140 are provided, the control circuits included in the substrate layer 110 may be electrically isolated from a bit line 150.

The bit line 150 disposed on the first oxide layer 140 may include a plurality of layers extending in the first direction D1. For example, the bit line 150 may include a first bit line layer 152 including titanium nitride (TiN), a second bit line layer 154 including tungsten (W), and a third bit line layer 156 including titanium nitride (TiN).

The resistance of the bit line 150 may be adjusted by adjusting the material of the plurality of layers included in the bit line 150.

When the second bit line layer 154 is exposed to oxygen, the tungsten (W) may be oxidized to cause disconnection and a defect. The first bit line layer 152 and the third bit line layer 156, which are included in the bit line 150, may prevent the second bit line layer 154 from being exposed to oxygen and oxidized.

In addition, since the titanium nitride TiN included in the first bit line layer 152 has a higher adhesion to silicon oxide than the tungsten (W), the first bit line layer 152 provided between the first oxide layer 140 and the second bit line layer 154 may improve the interface stability of the bit line 150.

The bit line 150 may formed by depositing the plurality of layers and then performing an etching process using a mask.

Referring to FIGS. 2A and 2B, a second bit line separation layer 170 and a third bit line separation layer 180 may be disposed between adjacent bit lines 150. According to an embodiment, the second bit line separation layer 170 may include silicon nitride, and the third bit line separation layer 180 may include silicon oxide.

The bit line 150 and a first gate 190 may be separated from each other by a first bit line separation layer 160.

The second bit line separation layer 170 and the third bit line separation layer 180 may function as spacers that electrically isolate the adjacent bit lines 150.

The first bit line separation layer 160 may be provided on each of the bit lines 150 to electrically isolate the bit line 150 from the first gate 190. The first bit line separation layer 160 may include silicon oxide (SiCO) containing carbon.

According to FIGS. 2B and 2C, an active region 240 may be disposed on the bit line 150 to be electrically connected with at least a portion of the bit line 150. The active region 240 may be electrically isolated from a second gate 260 by a second gate insulating layer 250.

The first gate 190 and the second gate 260 may each include a metal, a metal mixture, a metal alloy, poly silicon, or a combination thereof. For example, the first gate 190 and the second gate 260 may include titanium nitride.

Referring to FIG. 2C, a first gate insulating layer 220 may be disposed along the sidewall of the first gate 190.

According to an embodiment, the first gate insulating layer 220 may include a plurality of insulating layers having different dielectric constants.

For example, the first gate insulating layer 220 may include a lower gate insulating layer 222 in contact with the sidewall of the first gate 190 and the first bit line separation layer 160, and an upper gate insulating layer 224 located on the lower gate insulating layer 222 and in contact with the lower gate insulating layer 222 and the active region 240.

The lower gate insulating layer 222 may include, for example, silicon oxide (SiO₂) having a dielectric constant of about 3.9.

The upper gate insulating layer 224 may include, for example, a high-k material having a dielectric constant of 4 or more. According to an embodiment, the upper gate insulating layer 224 may have a dielectric constant of about 20 or more and may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In another embodiment, the upper gate insulating layer 224 may be formed of a composite layer including two or more layers of the high-k material mentioned above.

Since the first gate insulating layer 220 includes the upper gate insulating layer 224, the leakage current characteristics of the first gate insulating layer 220 may be improved.

In addition, in the semiconductor device according to an embodiment of the present disclosure, the upper gate insulating layer 224 is formed before the active region 240 is formed. Thus, the active region 240 may not be damaged by a high-temperature process of forming the upper gate insulating layer 224.

According to an embodiment, a second nitride layer 200 may be disposed on the first gate 190.

A third nitride layer 270 may be disposed between adjacent second gates 260, and a second oxide layer 280 may be formed on the third nitride layer 270.

A first contact region 310 disposed on the active region 240 may include the same oxide semiconductor material as the active region 240.

The first contact region 310 may be formed in a trench formed in a contact insulating layer 300.

A second contact region 330 overlapping the upper portion of the first contact region 310 may include metal, metal silicide, or metal nitride. The second contact region 330 may be a region formed to decrease the contact resistance between the first contact region 310 and a storage element 340.

The second contact region 330 may be a region formed in a storage element insulating layer 320. The second contact region 330 and the storage element 340 may be formed by etching at least a partial region of the storage element insulating layer 320.

The active region 240 may include a horizontal portion in contact with the bit line 150 and a vertical portion extending in the vertical direction (the direction D3) between the first gate 190 and the second gate 260.

The active region 240 may include, for example, an oxide semiconductor material, and the oxide semiconductor material may include indium gallium zinc oxide (IGZO).

According to another embodiment, the active region ACT may include doped poly silicon, undoped poly silicon, amorphous silicon, indium zinc oxide (IZO), indium tin oxide (ITO), and indium oxide (InO₃).

Since IGZO has low leakage current characteristics, a semiconductor device having low standby power may be implemented by forming the active region 240 with IGZO.

In addition, since the active region 240 includes IGZO, the difficulty level of a process for forming a three-dimensional semiconductor may be lowered, and an active region having a three-dimensional structure that includes a horizontal portion and a vertical section may be easily formed.

The first contact region 310 may overlap the upper portion of the upper gate insulating layer 224. Leakage current generated in the first contact region 310 may be prevented by the upper gate insulating layer 224.

The first contact region 310 may have a width greater than the width of the vertical portion of the active region 240 in the first direction (the direction D1). The first contact region 310 may have the same width as the second contact region 330.

Since the width of the first contact region 310 is greater than the width of the vertical portion of the active region 240, a contact area between the second contact region 330 and the first contact region 310 may be secured, and contact stability between the second contact region 330 and the first contact region 310 may be secured.

The second contact region 330 may include metal, metal silicide, or metal nitride. The storage element 340 located on the second contact region 330 may be disposed to at least partially overlap the second contact region 330.

The contact insulating layer 300 may be provided in a form that surrounds the first contact region 310. In other words, the contact insulating layer 300 may be disposed between adjacent first contact regions 310.

The layer in which the storage element 340 is disposed may be referred to as a storage element layer.

The storage element layer may include at least a portion of the second contact regions 330. In addition, the storage element layer may include the storage elements 340 overlapping the upper portions of the second contact regions 330 and may include the storage element insulating layer 320 located between the storage elements 340 and located between the second contact regions 330.

Each of the storage elements 340 may operate as a data storage for writing or reading data depending on control signals applied to the semiconductor device.

Each of the storage elements 340 may include a capacitor dielectric film and storage electrodes. It may be determined whether or not to provide a voltage to the storage element 340 and the magnitude of the voltage provided to the storage element 340 depending on control signals provided to the first gate 190 and the second gate 260. The semiconductor device may read out stored data based on a signal corresponding to the voltage of the storage element 340.

The storage element 340 may have a shape extending in the vertical direction (the third direction D3) with respect to the substrate layer 110 in the storage element layer. More specifically, the storage element 340 may have a cylinder or pillar shape. As the storage element 340 has a cylinder or pillar shape, the number of storage elements 340 disposed in the same area may be increased. When the number of storage elements 340 disposed in the same area is increased, the data storage capacity of the semiconductor device may be increased.

Each of the storage elements 340 may correspond to one second contact region 330, and the one second contact region 330 may be in contact with one storage element 340.

In the semiconductor device according to an embodiment of the present disclosure, a ground voltage and a word line driving voltage may be provided to the first gate 190 and the second gate 260, respectively, at read/write timing of data. When the ground voltage is provided to the first gate 190, the first gate 190 may provide a back-bias within the semiconductor device.

The first gate 190 may be located between adjacent two second gates 260. As the ground voltage is provided to the first gate 190, the adjacent second gates 260 may be electrically isolated from each other.

When the adjacent second gates 260 are electrically isolated from each other, this may mean that electrical interference between the adjacent second gates 260 is blocked.

As the semiconductor device is made compact, the distance between the second gates 260 may be decreased. When the distance between the second gates 260 is decreased, a coupling phenomenon may occur between the adjacent second gates 260 by the word line driving voltage provided to each of the second gates 260. Due to the coupling phenomenon, an error may occur during data read/write operations of the semiconductor device.

According to an embodiment of the present disclosure, by providing the first gate 190 between the second gates 260 and providing the ground voltage to the first gate 190, the coupling phenomenon between the second gates 260 may be prevented, and thus the operating characteristics of the semiconductor device may be improved. Furthermore, by providing the ground voltage to the first gate 290, a coupling phenomenon between adjacent active regions 240 may be prevented during operation of the semiconductor device.

Moreover, by providing the back-bias to the semiconductor device by the first gate 190 to which the ground voltage is provided, leakage current (e.g., gate induced drain leakage (GIDL)) may be efficiently suppressed, and the electrical characteristics of the semiconductor device may be improved. In addition, by providing the back-bias to the semiconductor device by the first gate 190, the threshold voltage characteristics of the semiconductor device may be adjusted.

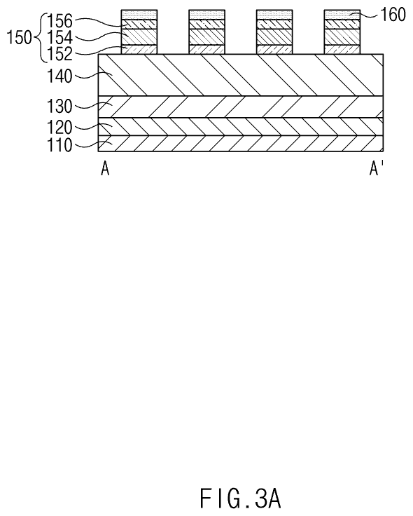

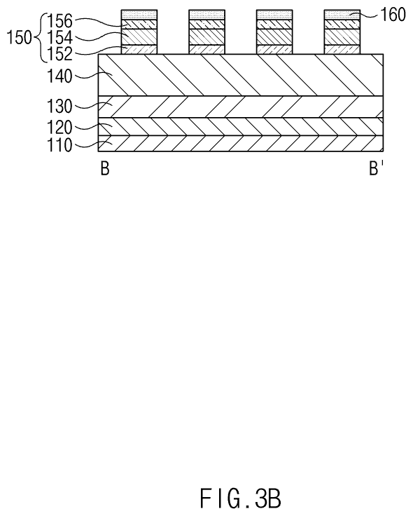

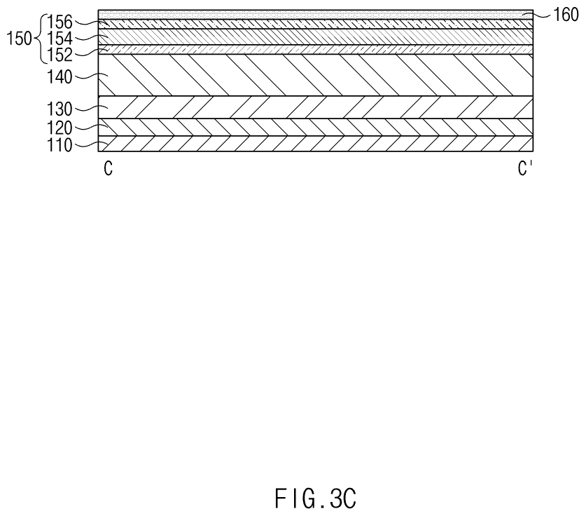

FIGS. 3A to 3C are views for explaining a method for forming the bit line included in the semiconductor device according to an embodiment of the present disclosure.

More specifically, FIGS. 3A to 3C are sectional views illustrating a fabrication step of the semiconductor device in which the bit line 150 is formed on the substrate layer 110, the silicide layer 120, the first nitride layer 130, and the first oxide layer 140 and the first bit line separation layer 160 is formed on the bit line 150.

FIG. 3A is a sectional view obtained by cutting the center of the region where the first gate G1 of the semiconductor device is formed, along a cutting line (line A-A′ of FIG. 1) parallel to the second direction D2 in the fabrication step.

FIG. 3B is a sectional view obtained by cutting the center of the region where the second gate G2 of the semiconductor device is formed, along a cutting line (line B-B′ of FIG. 1) parallel to the second direction D2 in the fabrication step.

FIG. 3C is a sectional view obtained by cutting the center of the bit line BL of the semiconductor device along a cutting line (line C-C′ of FIG. 1) parallel to the first direction D1 in the fabrication step.

Referring to FIGS. 3A to 3C, the substrate layer 110 may include a semiconductor substrate.

The silicide layer 120 may be located on the substrate layer 110 and may include a metal silicide material such as cobalt silicide (CoSi).

The first nitride layer 130 may be formed on the silicide layer 120 and may include silicon nitride.

The first oxide layer 140 may be formed on the first nitride layer 130 and may include silicon oxide.

The structure of the substrate layer 110, the silicide layer 120, the first nitride layer 130, and the first oxide layer 140 may be substantially the same as that described with reference to FIGS. 2A, 2B, and 2C.

The bit line 150 may include the first bit line layer 152 including titanium nitride (TIN), the second bit line layer 154 including tungsten (W), and the third bit line layer 156 including titanium nitride (TIN).

Since the bit line 150 includes the plurality of layers, the operation resistance of the semiconductor device may be adjusted.

The first bit line layer 152 and the third bit line layer 156, which are included in the bit line 150, may prevent the second bit line layer 154 from being exposed to oxygen and oxidized. When the second bit line layer 154 is exposed to oxygen, the tungsten (W) may be oxidized to cause disconnection and a defect.

In addition, since the titanium nitride (TiN) included in the first bit line layer 152 has a higher adhesion to silicon oxide than the tungsten (W), the first bit line layer 152 provided between the first oxide layer 140 and the second bit line layer 154 may improve the mechanical stability of the bit line 150.

The bit line 150 may be formed by depositing the plurality of layers and then performing an etching process using a mask.

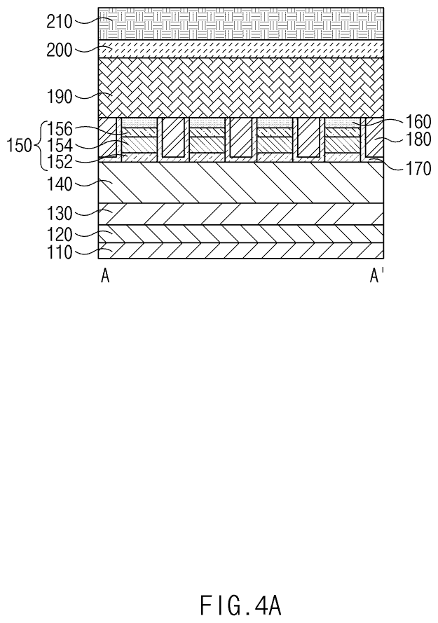

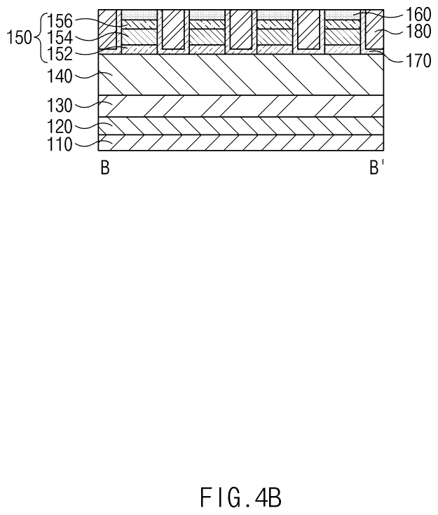

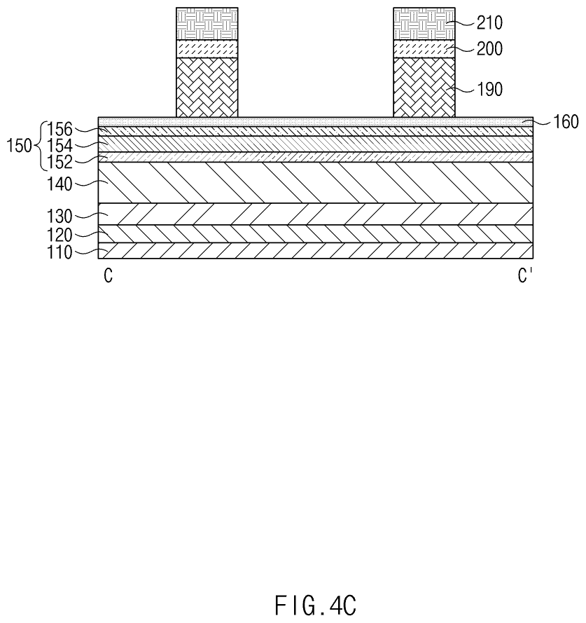

FIGS. 4A to 4C are views for explaining a method for forming the first gate included in the semiconductor device according to an embodiment of the present disclosure.

More specifically, FIGS. 4A to 4C are sectional views illustrating a fabrication step of the semiconductor device in which the second bit line separation layer 170 and the third bit line separation layer 180 are formed between the bit lines 150 and the first gate 190 is formed on the first bit line separation layer 160.

FIG. 4A is a sectional view obtained by cutting the center of the region where the first gate G1 of the semiconductor device is formed, along a cutting line (line A-A′ of FIG. 1) parallel to the second direction D2 in the fabrication step.

FIG. 4B is a sectional view obtained by cutting the center of the region where the second gate G2 of the semiconductor device is formed, along a cutting line (line B-B′ of FIG. 1) parallel to the second direction D2 in the fabrication step.

FIG. 4C is a sectional view obtained by cutting the center of the bit line BL of the semiconductor device along a cutting line (line C-C′ of FIG. 1) parallel to the first direction D1 in the fabrication step.

Referring to FIGS. 4A to 4C, the second bit line separation layer 170 and the third bit line separation layer 180 may be disposed between adjacent bit lines 150.

According to an embodiment, the second bit line separation layer 170 may include silicon nitride, and the third bit line separation layer 180 may include silicon oxide.

The first gate 190 may be selectively formed on the first bit line separation layer 160. The first gate 190 may have a shape extending in the second direction D2. The first gate 190 may include a metal, a metal mixture, a metal alloy, titanium nitride, tungsten, poly silicon, or a combination thereof. For example, the first gate 190 may include titanium nitride.

The first gate 190 may be selectively formed on a partial region of the first bit line separation layer 160 by forming a conductive material layer including metal, metal nitride, and poly silicon on the first bit line separation layer 160 and selectively etching the formed conductive material layer.

The second nitride layer 200 and a protective oxide layer 210 may be formed on the first gate 190. The second nitride layer 200 and the protective oxide layer 210 may perform a function of preventing damage to the first gate 190 during a semiconductor process and electrically isolating the first gate 190 from other components (e.g., the active region) in the semiconductor device. The protective oxide layer 210 may include a silicon oxide material, and the second nitride layer 200 may include a silicon nitride material.

More specifically, as illustrated in FIGS. 4B and 4C, the first gate 190 may be selectively formed in a region other than the region where the second gate is formed.

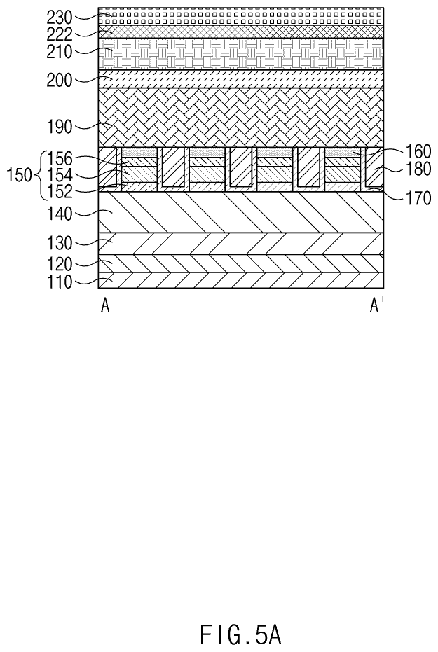

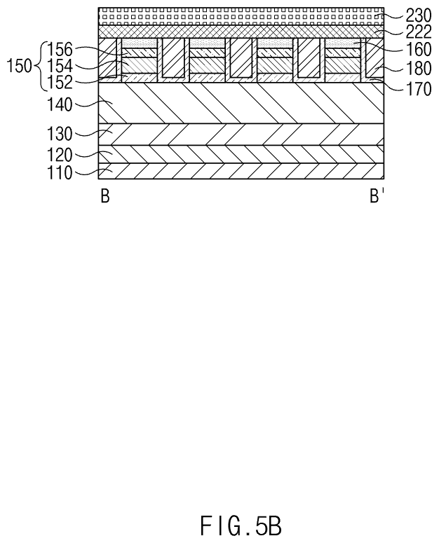

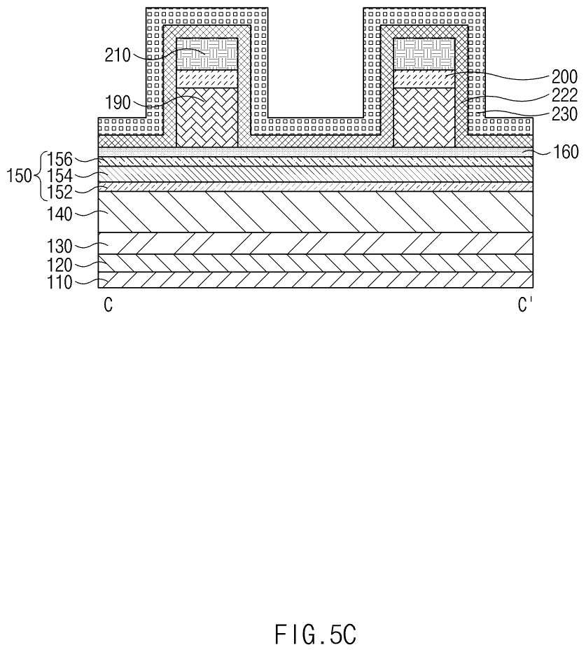

FIGS. 5A to 5C are views for explaining a method for forming the lower gate insulating layer included in the semiconductor device according to an embodiment of the present disclosure.

More specifically, FIGS. 5A to 5C are sectional views illustrating a fabrication step of the semiconductor device in which the lower gate insulating layer 222 and a protective silicon layer 230 are formed on the first gate 190.

FIG. 5A is a sectional view obtained by cutting the center of the region where the first gate G1 of the semiconductor device is formed, along a cutting line (line A-A′ of FIG. 1) parallel to the second direction D2 in the fabrication step.

FIG. 5B is a sectional view obtained by cutting the center of the region where the second gate G2 of the semiconductor device is formed, along a cutting line (line B-B′ of FIG. 1) parallel to the second direction D2 in the fabrication step.

FIG. 5C is a sectional view obtained by cutting the center of the bit line BL of the semiconductor device along a cutting line (line C-C′ of FIG. 1) parallel to the first direction D1 in the fabrication step.

Referring to FIGS. 5A to 5C, the lower gate insulating layer 222 and the protective silicon layer 230 may be formed in contact with the upper portion and the side surface of the first gate 190.

The lower gate insulating layer 222 may include silicon oxide. Th protective silicon layer 230 may include poly silicon and may overlap the upper portion of the lower gate insulating layer 222 to protect the lower gate insulating layer 222 during an etching process.

When the protective silicon layer 230 is not provided, the lower gate insulating layer 222 may be directly exposed to plasma during the etching process, and side effects such as a decrease in the thickness of the lower gate insulating layer 222 or a surface defect due to the plasma may occur.

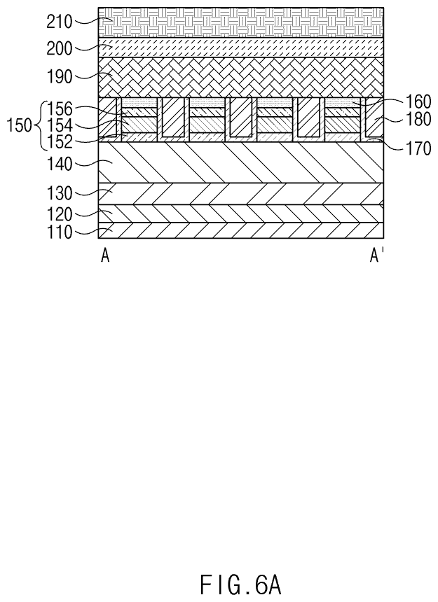

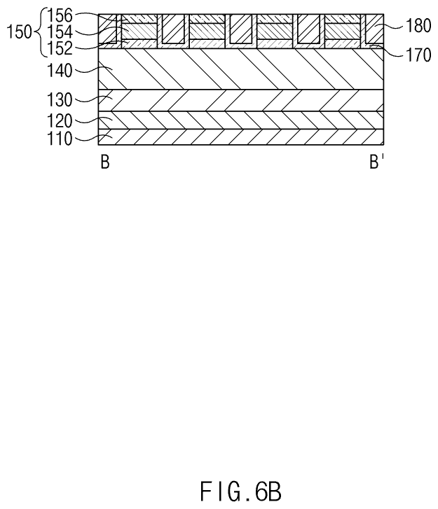

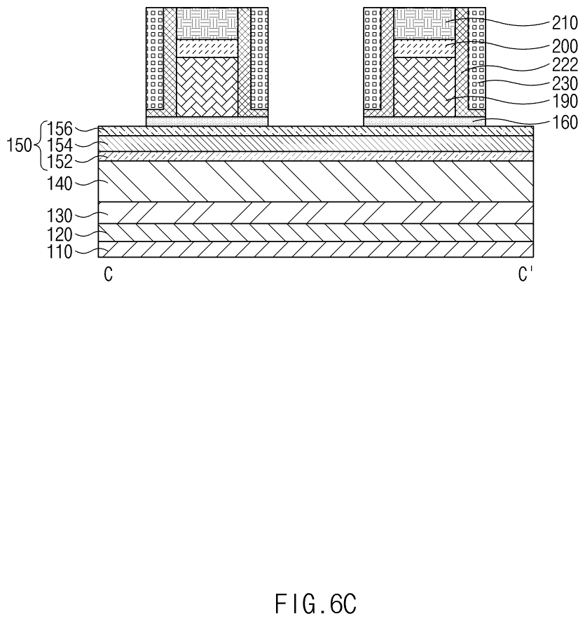

FIGS. 6A to 6C are views for explaining a method for forming the lower gate insulating layer included in the semiconductor device according to an embodiment of the present disclosure.

More specifically, FIGS. 6A to 6C are sectional views illustrating a fabrication step of the semiconductor device in which at least partial regions of the lower gate insulating layer 222 and the protective silicon layer 230 are etched.

FIG. 6A is a sectional view obtained by cutting the center of the region where the first gate G1 of the semiconductor device is formed, along a cutting line (line A-A′ of FIG. 1) parallel to the second direction D2 in the fabrication step.

FIG. 6B is a sectional view obtained by cutting the center of the region where the second gate G2 of the semiconductor device is formed, along a cutting line (line B-B′ of FIG. 1) parallel to the second direction D2 in the fabrication step.

FIG. 6C is a sectional view obtained by cutting the center of the bit line BL of the semiconductor device along a cutting line (line C-C′ of FIG. 1) parallel to the first direction D1 in the fabrication step.

Referring to FIGS. 6A to 6C, the lower gate insulating layer 222 and the protective silicon layer 230 in contact with the upper portion of the bit line 150 may be removed through an etching process.

As partial regions of the lower gate insulating layer 222 and the protective silicon layer 230 are selectively removed, only the lower gate insulating layer 222 in contact with the sidewall of the first gate 190 and the first bit line separation layer 160 may be selectively left.

In addition, the protective silicon layer 230 that overlaps the lower gate insulating layer 222 in contact with the sidewall of the first gate 190 and the first bit line separation layer 160 may be selectively left.

Thereafter, the remaining protective silicon layer 230 may be selectively removed through a separate silicon etching process. The silicon etching process may include, for example, a wet etching process.

The lower gate insulating layer 222 may include silicon oxide, and the silicon oxide may have a dielectric constant of about 3.9.

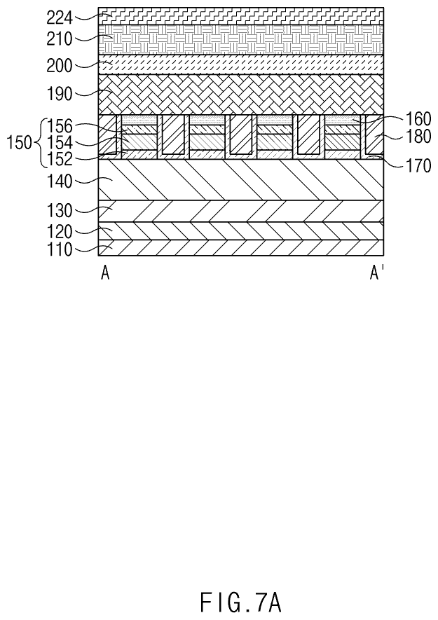

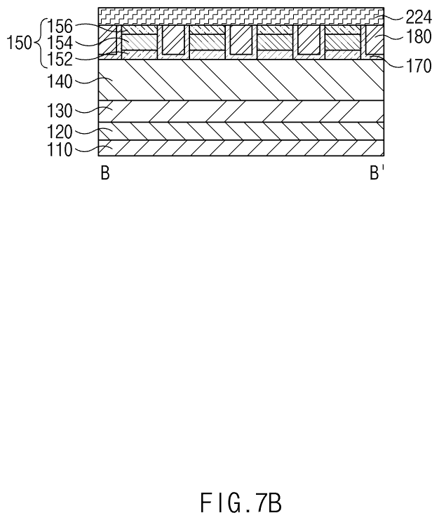

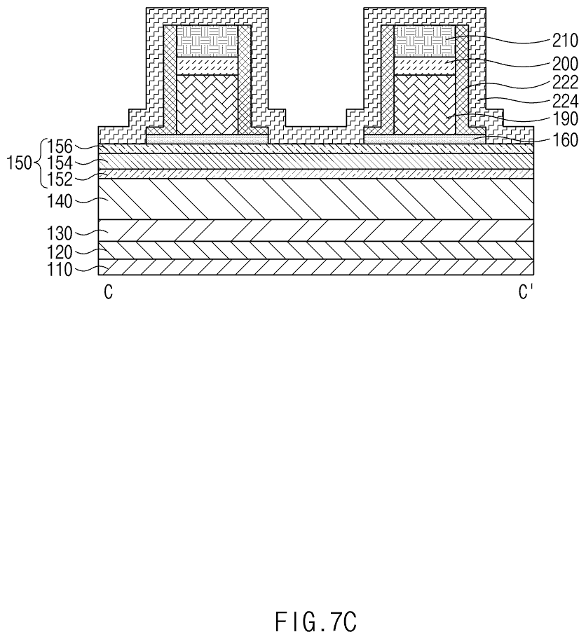

FIGS. 7A to 7C are views for explaining a method for forming the upper gate insulating layer included in the semiconductor device according to an embodiment of the present disclosure.

More specifically, FIGS. 7A to 7C are sectional views illustrating a fabrication step of the semiconductor device in which the upper gate insulating layer 224 is formed on the lower gate insulating layer 222.

FIG. 7A is a sectional view obtained by cutting the center of the region where the first gate G1 of the semiconductor device is formed, along a cutting line (line A-A′ of FIG. 1) parallel to the second direction D2 in the fabrication step.

FIG. 7B is a sectional view obtained by cutting the center of the region where the second gate G2 of the semiconductor device is formed, along a cutting line (line B-B′ of FIG. 1) parallel to the second direction D2 in the fabrication step.

FIG. 7C is a sectional view obtained by cutting the center of the bit line BL of the semiconductor device along a cutting line (line C-C′ of FIG. 1) parallel to the first direction D1 in the fabrication step.

Referring to FIGS. 7A to 7C, the upper gate insulating layer 224 may include a high-k material having a higher dielectric constant than silicon oxide.

The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃).

The upper gate insulating layer 224 may be formed to overlap the upper portion of the lower gate insulating layer 222 and the upper portion of the bit line 150 and may be formed on the second bit line separation layer 170 and the third bit line separation layer 180.

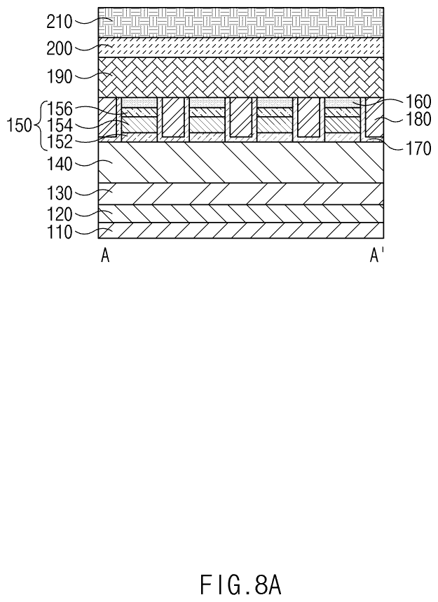

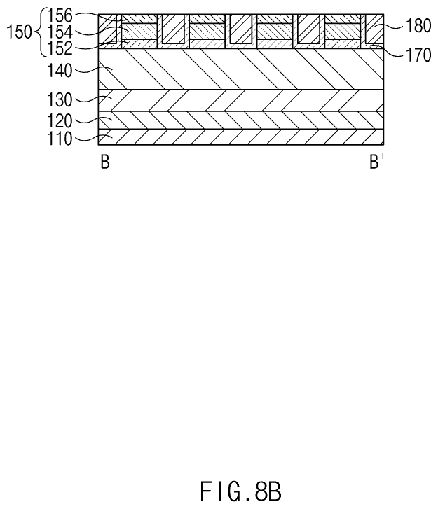

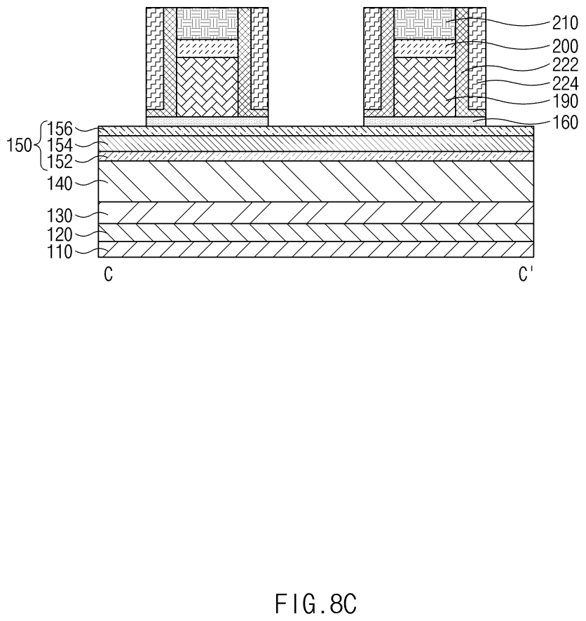

FIGS. 8A to 8C are views for explaining a method for forming the upper gate insulating layer included in the semiconductor device according to an embodiment of the present disclosure.

More specifically, FIGS. 8A to 8C are sectional views illustrating a fabrication step of the semiconductor device in which at least a partial region of the upper gate insulating layer 224 is etched.

FIG. 8A is a sectional view obtained by cutting the center of the region where the first gate G1 of the semiconductor device is formed, along a cutting line (line A-A′ of FIG. 1) parallel to the second direction D2 in the fabrication step.

FIG. 8B is a sectional view obtained by cutting the center of the region where the second gate G2 of the semiconductor device is formed, along a cutting line (line B-B′ of FIG. 1) parallel to the second direction D2 in the fabrication step.

FIG. 8C is a sectional view obtained by cutting the center of the bit line BL of the semiconductor device along a cutting line (line C-C′ of FIG. 1) parallel to the first direction D1 in the fabrication step.

Referring to FIGS. 8A to 8C, as a partial region of the upper gate insulating layer 224 formed on the first gate 190 and a partial region of the upper gate insulating layer 224 formed on the bit line 150 are etched, the upper gate insulating layer 224 overlapping the upper portion of the lower gate insulating layer 222 may be selectively left. The upper gate insulating layer 224 may be selectively removed through an etching process.

The lower gate insulating layer 222 and the upper gate insulating layer 224 may be referred to as the first gate insulating layer 220. In other words, the first gate insulating layer 220 may include a plurality of dielectric layers.

Since the first gate insulating layer 220 includes the plurality of dielectric layers, the leakage current characteristics of the first gate insulating layer 220 may be improved.

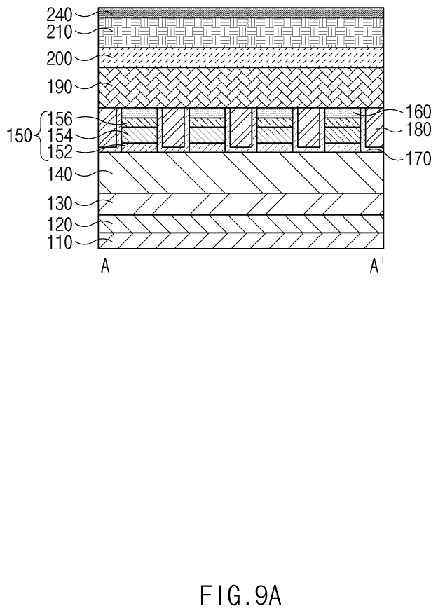

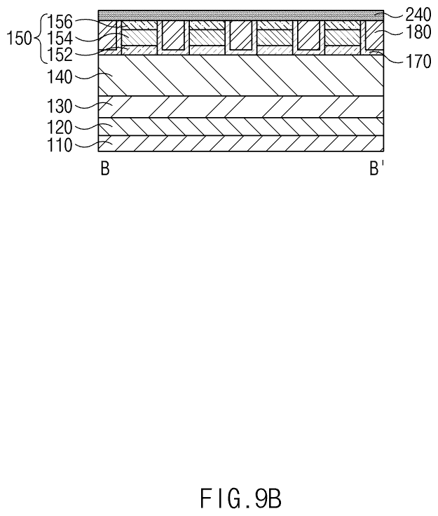

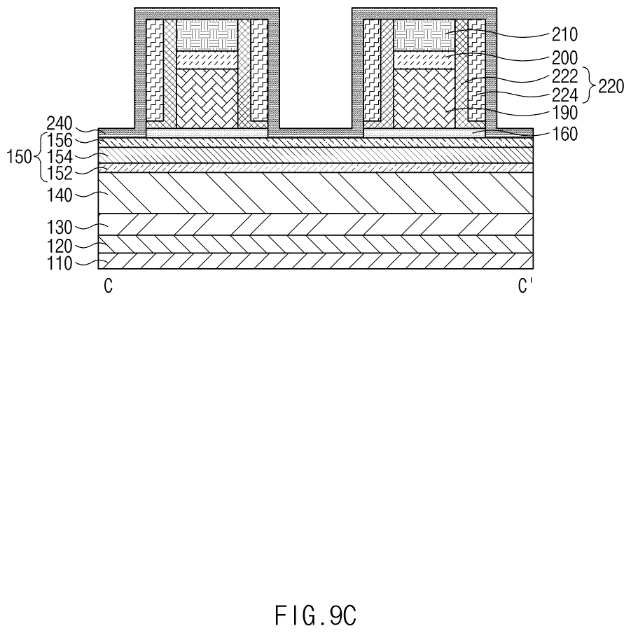

FIGS. 9A to 9C are views for explaining a method for forming the active region included in the semiconductor device according to an embodiment of the present disclosure.

More specifically, FIGS. 9A to 9C are sectional views illustrating a fabrication step of the semiconductor device in which the active region 240 is formed on the first gate insulating layer 220 and the bit line 150.

FIG. 9A is a sectional view obtained by cutting the center of the region where the first gate G1 of the semiconductor device is formed, along a cutting line (line A-A′ of FIG. 1) parallel to the second direction D2 in the fabrication step.

FIG. 9B is a sectional view obtained by cutting the center of the region where the second gate G2 of the semiconductor device is formed, along a cutting line (line B-B′ of FIG. 1) parallel to the second direction D2 in the fabrication step.

FIG. 9C is a sectional view obtained by cutting the center of the bit line BL of the semiconductor device along a cutting line (line C-C′ of FIG. 1) parallel to the first direction D1 in the fabrication step.

Referring to FIGS. 9A to 9C, the active region 240 may include a semiconductor material or an oxide semiconductor material.

The active region 240 may include doped poly silicon, undoped poly silicon, amorphous silicon, amorphous indium gallium zinc oxide (IGZO) semiconductor, indium zinc oxide (IZO), indium tin oxide (ITO), and indium oxide (InO₃).

At least a partial region of the active region 240 may be electrically connected with the bit line 150.

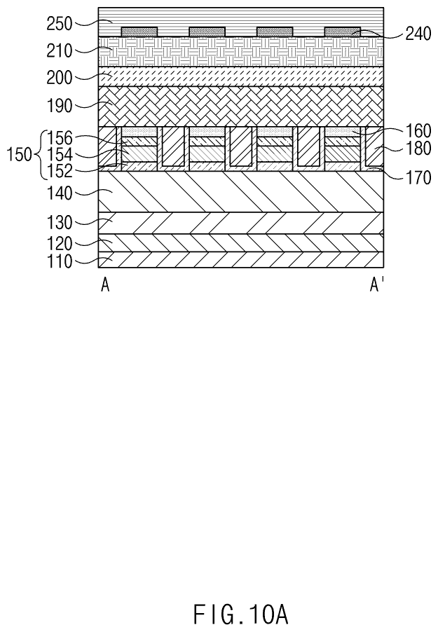

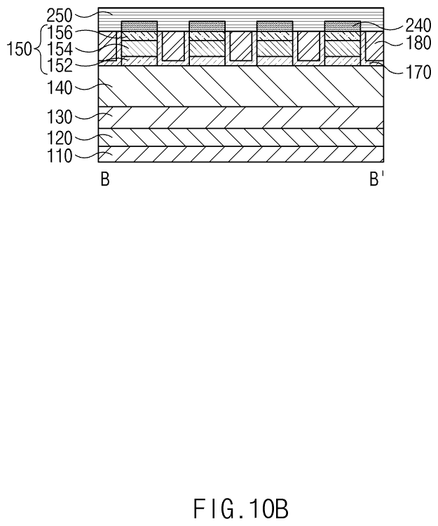

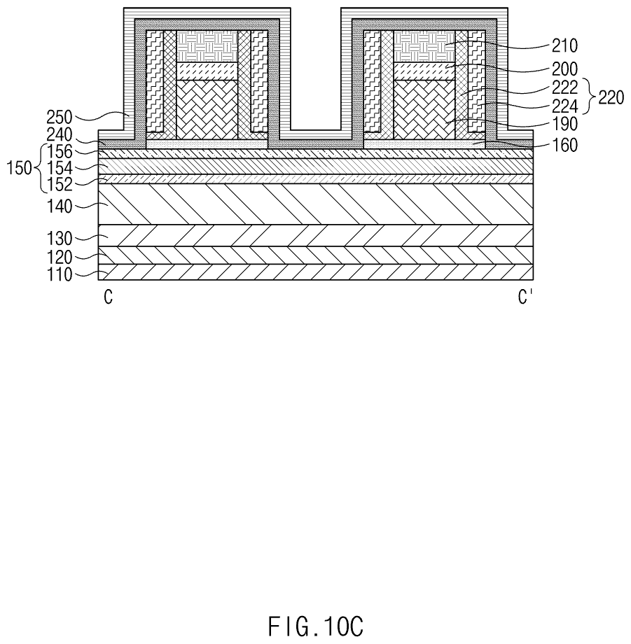

FIGS. 10A to 10C are views for explaining a method for forming the second gate insulating layer included in the semiconductor device according to an embodiment of the present disclosure.

More specifically, FIGS. 10A to 10C are sectional views illustrating a fabrication step of the semiconductor device in which adjacent active regions 240 are separated from each other and the second gate insulating layer 250 overlapping the upper portions of the active regions 240 is formed.

FIG. 10A is a sectional view obtained by cutting the center of the region where the first gate G1 of the semiconductor device is formed, along a cutting line (line A-A′ of FIG. 1) parallel to the second direction D2 in the fabrication step.

FIG. 10B is a sectional view obtained by cutting the center of the region where the second gate G2 of the semiconductor device is formed, along a cutting line (line B-B′ of FIG. 1) parallel to the second direction D2 in the fabrication step.

FIG. 10C is a sectional view obtained by cutting the center of the bit line BL of the semiconductor device along a cutting line (line C-C′ of FIG. 1) parallel to the first direction D1 in the fabrication step.

Referring to FIGS. 10A to 10C, the adjacent active regions 240 may be separated from each other by forming a mask overlapping the active region 240 and selectively etching at least a partial region of the active region 240. The mask for etching may include a spin on carbon (SOC) layer and a silicon oxynitride (SiON) layer.

The second gate insulating layer 250 may include silicon oxide and may electrically isolate the adjacent active regions 240 or may electrically isolate the active regions 240 from the second gate 260 to be formed later.

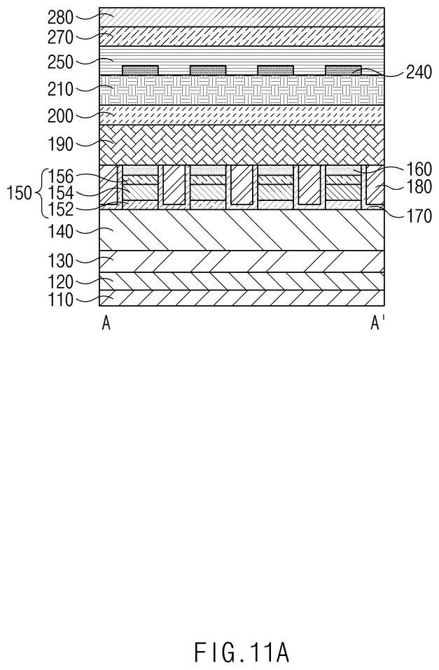

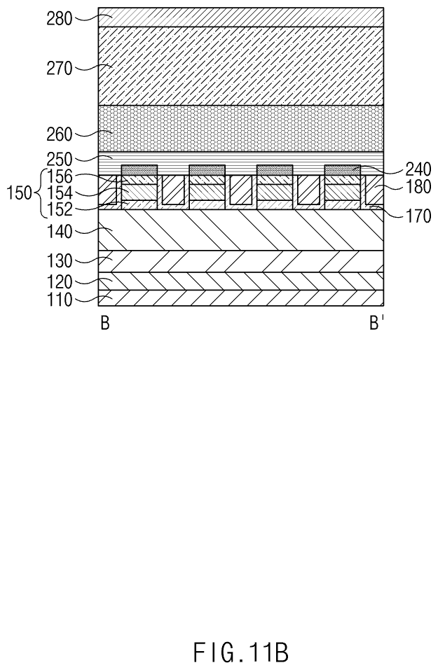

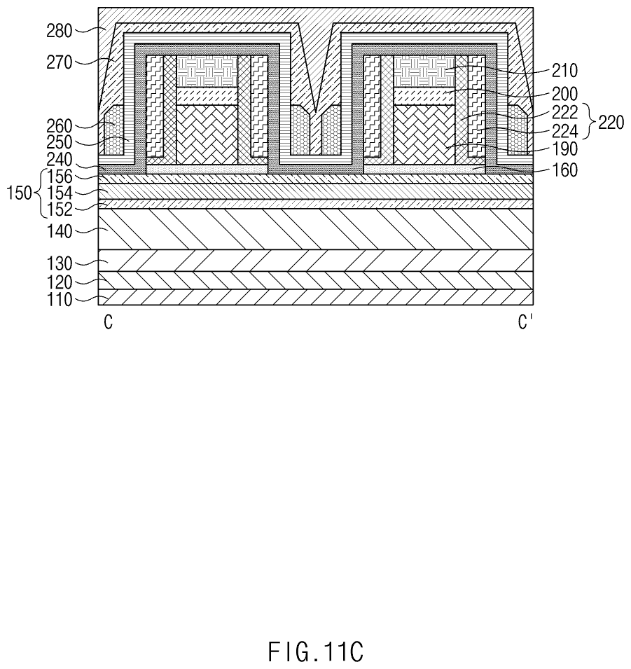

FIGS. 11A to 11C are views for explaining a method for forming the second gate included in the semiconductor device according to an embodiment of the present disclosure.

More specifically, FIGS. 11A to 11C are sectional views illustrating a fabrication step of the semiconductor device in which the second gate 260 is formed and the third nitride layer 270 and the second oxide layer 280 that overlap the upper portion of the second gate 260 are formed.

FIG. 11A is a sectional view obtained by cutting the center of the region where the first gate G1 of the semiconductor device is formed, along a cutting line (line A-A′ of FIG. 1) parallel to the second direction D2 in the fabrication step.

FIG. 11B is a sectional view obtained by cutting the center of the region where the second gate G2 of the semiconductor device is formed, along a cutting line (line B-B′ of FIG. 1) parallel to the second direction D2 in the fabrication step.

FIG. 11C is a sectional view obtained by cutting the center of the bit line BL of the semiconductor device along a cutting line (line C-C′ of FIG. 1) parallel to the first direction D1 in the fabrication step.

Referring to FIGS. 11A to 11C, the second gate 260 may face the first gate 190 and may have a shape extending in the second direction D2. The second gate 260 may include a metal, a metal mixture, a metal alloy, titanium nitride, tungsten, poly silicon, or a combination thereof. For example, the second gate 260 may include titanium nitride.

The second gate 260 may be formed by forming a conductive material layer including metal, metal nitride, and poly silicon and selectively etching the formed conductive material layer.

The third nitride layer 270 may be formed on the second gate 260 and may include silicon nitride. The third nitride layer 270 may be disposed on the second gate 260 and may electrically isolate the second gate 260 from another adjacent second gate 260.

The second oxide layer 280 may be formed on the third nitride layer 270 and may include silicon oxide.

A mask may be formed over the second oxide layer 280 to form a contact portion located at one end of the first gate 190 in the second direction D2 and a contact portion located at one end of the second gate 260 in the second direction D2. After the mask is formed, the contact portions may be formed through an etching process, and the second oxide layer 280 may protect the first gate 190 and the second gate 260 during the etching process.

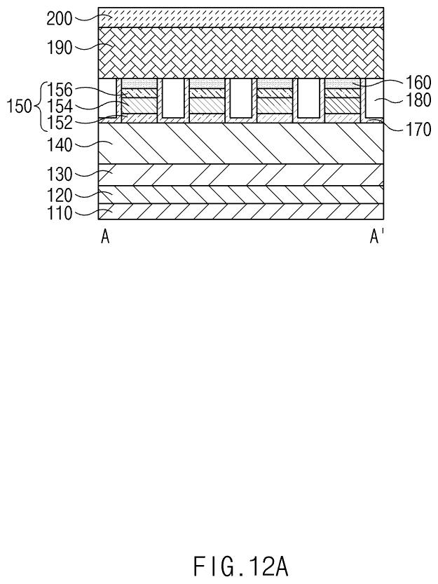

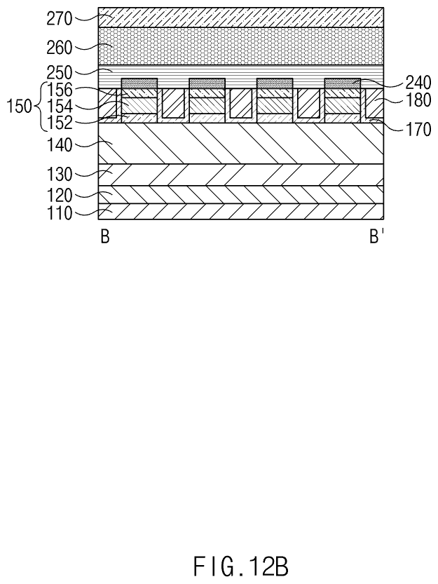

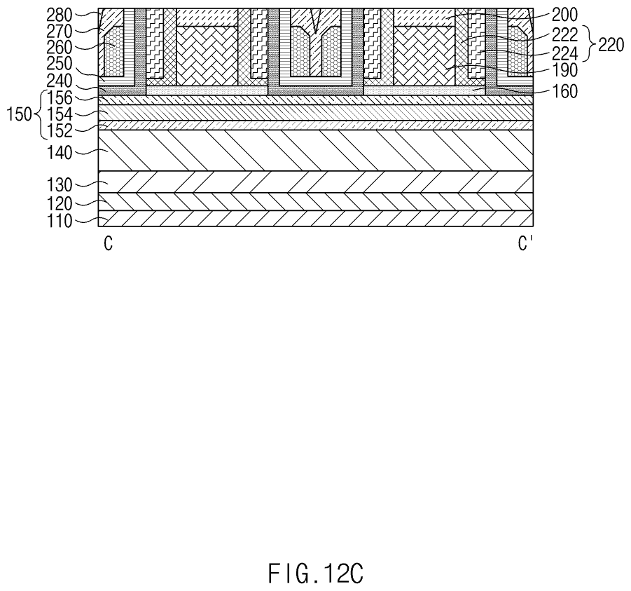

FIGS. 12A to 12C are views for explaining a method for forming the capacitor included in the semiconductor device according to an embodiment of the present disclosure.

More specifically, FIGS. 12A to 12C are sectional views illustrating a fabrication step of the semiconductor device in which portions of the third nitride layer 270 and the second oxide layer 280 are removed.

FIG. 12A is a sectional view obtained by cutting the center of the region where the first gate G1 of the semiconductor device is formed, along a cutting line (line A-A′ of FIG. 1) parallel to the second direction D2 in the fabrication step.

FIG. 12B is a sectional view obtained by cutting the center of the region where the second gate G2 of the semiconductor device is formed, along a cutting line (line B-B′ of FIG. 1) parallel to the second direction D2 in the fabrication step.

FIG. 12C is a sectional view obtained by cutting the center of the bit line BL of the semiconductor device along a cutting line (line C-C′ of FIG. 1) parallel to the first direction D1 in the fabrication step.

Referring to FIGS. 12A to 12C, the third nitride layer 270 and the second oxide layer 280 may be removed through a chemical mechanical polishing (CMP).

The vertical portion included in the active region 240 may be exposed by removing the third nitride layer 270, a partial region of the second oxide layer 280, a partial region of the second gate layer 250, a partial region of the first gate insulating layer 220, the protective oxide layer 210, and a partial region of the active region 240.

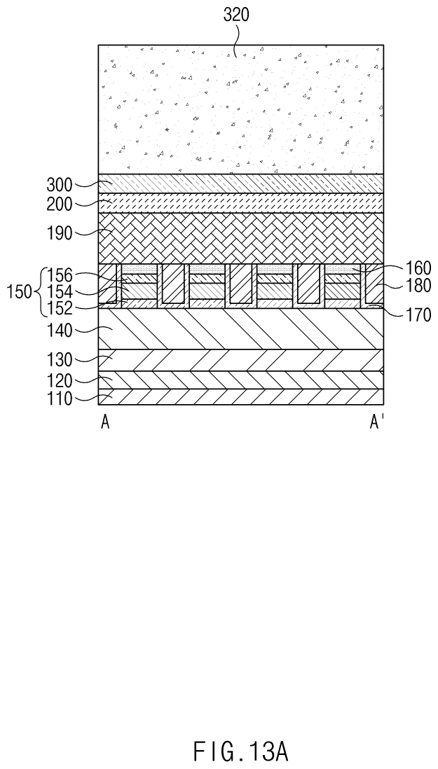

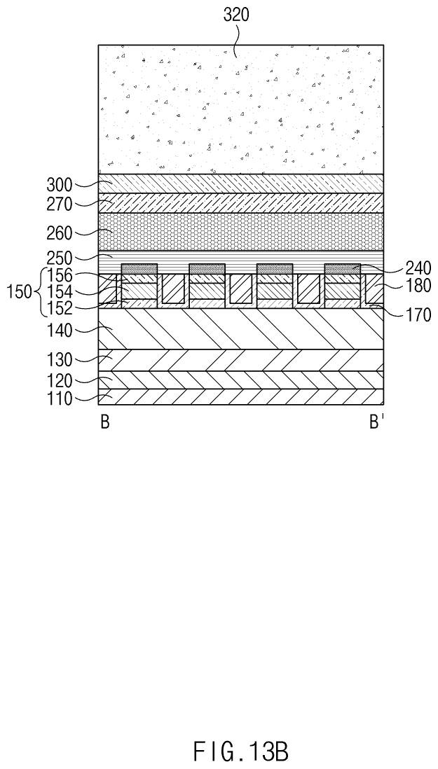

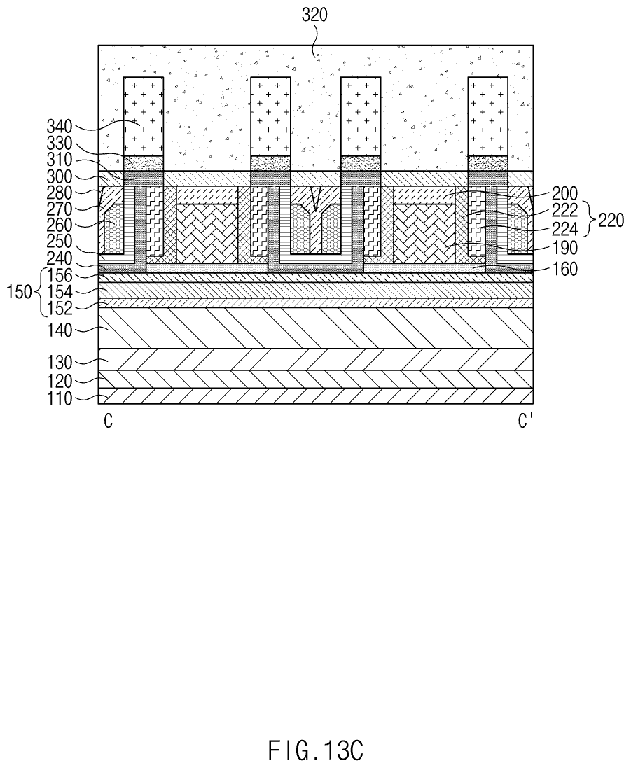

FIGS. 13A to 13C are views for explaining a method for forming the capacitor included in the semiconductor device according to an embodiment of the present disclosure.

More specifically, FIGS. 13A to 13C are sectional views illustrating a fabrication step of the semiconductor device in which the first contact region 310 and the second contact region 330 are formed on the active region 240 and the storage element 340 is disposed on the second contact region 330.

FIG. 13A is a sectional view obtained by cutting the center of the region where the first gate G1 of the semiconductor device is formed, along a cutting line (line A-A′ of FIG. 1) parallel to the second direction D2 in the fabrication step.

FIG. 13B is a sectional view obtained by cutting the center of the region where the second gate G2 of the semiconductor device is formed, along a cutting line (line B-B′ of FIG. 1) parallel to the second direction D2 in the fabrication step.

FIG. 13C is a sectional view obtained by cutting the center of the bit line BL of the semiconductor device along a cutting line (line C-C′ of FIG. 1) parallel to the first direction D1 in the fabrication step.

Referring to FIGS. 13A to 13C, the first contact region 310 and the second contact region 330 may be formed by sequentially stacking an oxide semiconductor layer and a conductive material layer and selectively etching the regions where the first contact region 310 and the second contact region 330 are not formed.

The contact insulating layer 300 may be formed between the first contact regions 310. The contact insulating layer 300 may include an insulating material such as silicon oxide and may electrically isolate the adjacent first contact regions 310.

The second contact regions 330 may be separated from each other by the storage element insulating layer 320 included in the storage element layer.

The storage element 340 may have a shape overlapping at least a portion of the second contact region 330.

The storage element 340 may be a data storage for writing or reading data and may include, for example, a MIM capacitor.

As described above, the semiconductor device of the present disclosure may include the three-dimensional channel. Thus, the semiconductor device with improved integration may be provided.

In addition, the semiconductor device of the present disclosure may include the upper gate insulating layer and the lower gate insulating layer between the first gate and the active region. Thus, the semiconductor device with improved leakage current characteristics may be provided.

In addition, the disclosure may provide various effects that are directly or indirectly recognized.

Hereinabove, although the present disclosure has been described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

What is claimed is:

1. A semiconductor device comprising:
a bit line extending in a first direction;
a first gate extending in a second direction perpendicular to the first direction;
a second gate extending parallel to the first gate;
an active region including
a vertical portion between the first gate and the second gate, and
a horizontal portion in contact with the bit line and the vertical portion; and
a first gate insulating layer disposed between the first gate and the vertical portion,
wherein the first gate insulating layer includes a lower gate insulating layer in contact with the first gate and an upper gate insulating layer in contact with the vertical portion, and
wherein the upper gate insulating layer has a higher dielectric constant than the lower gate insulating layer.

2. The semiconductor device of claim 1, further comprising:
a second gate insulating layer disposed between the second gate and the active region.

3. The semiconductor device of claim 1, wherein the active region includes an indium gallium zinc oxygen semiconductor, and
wherein the active region includes a channel region formed therein.

4. The semiconductor device of claim 1, further comprising:
a first contact region on an opposite side of the vertical portion; and
a second contact region overlapping the first contact region.

5. The semiconductor device of claim 4, wherein the first contact region includes a same material as the active region, and
wherein the second contact region includes at least one of metal, metal silicide, or metal nitride.

6. The semiconductor device of claim 4, further comprising:
a capacitor overlapping the second contact region.

7. The semiconductor device of claim 1, wherein the first gate is configured to receive a control signal different from a control signal provided to the second gate.

8. The semiconductor device of claim 1, wherein the lower gate insulating layer includes silicon oxide, and the upper gate insulating layer includes at least one of hafnium oxide, zirconium oxide, aluminum oxide, lanthanum oxide, titanium oxide, tantalum oxide, niobium oxide, or strontium titanium oxide.

9. A semiconductor device comprising:
a bit line extending in a first direction;
a first gate extending in a second direction perpendicular to the first direction;
a pair of second gates on opposite sides of the first gate and extending parallel to the first gate;
an active region including a vertical portion between one of the pair of second gates and the first gate, and a horizontal portion in contact with one side of the vertical portion and extending in the first direction; and
a first gate insulating layer disposed between the first gate and the active region,
wherein the first gate insulating layer includes a lower gate insulating layer in contact with the first gate and an upper gate insulating layer in contact with the vertical portion, and
wherein the upper gate insulating layer has a higher dielectric constant than the lower gate insulating layer.

10. The semiconductor device of claim 9, wherein the bit line is in contact with the horizontal portion.

11. The semiconductor device of claim 9, further comprising:
a second gate insulating layer disposed between one of the pair of the second gates and the active region.

12. The semiconductor device of claim 9, wherein the active region includes an amorphous indium gallium zinc oxygen semiconductor.

13. The semiconductor device of claim 9, further comprising:
a first contact region on an opposite side of the vertical portion; and
a second contact region overlapping the first contact region.

14. The semiconductor device of claim 13, wherein the first contact region includes a same material as the active region, and
wherein the second contact region includes at least one of metal, metal silicide, or metal nitride.

15. The semiconductor device of claim 14, further comprising:
a capacitor overlapping the second contact region.

16. The semiconductor device of claim 9, wherein the lower gate insulating layer includes silicon oxide, and the upper gate insulating layer includes at least one of hafnium oxide, zirconium oxide, aluminum oxide, lanthanum oxide, titanium oxide, tantalum oxide, niobium oxide, or strontium titanium oxide.

17. A method for fabricating a semiconductor device, the method comprising:
forming, in a substrate, a bit line extending in a first direction;
forming, on the bit line, a first gate extending in a second direction perpendicular to the first direction;
forming a first gate insulating layer in contact with the first gate; forming an active region including a vertical portion and a horizontal portion, the vertical portion extending along a sidewall of the first gate insulating layer, the horizontal portion being in contact with the bit line;
forming a second gate insulating layer in contact with the active region; and
forming a second gate in contact with the second gate insulating layer,
wherein the forming of the first gate insulating layer includes:
forming a lower gate insulating layer in contact with the first gate; and
forming an upper gate insulating layer on the lower gate insulating layer, and
wherein the upper gate insulating layer has a higher dielectric constant than the lower gate insulating layer.

18. The method of claim 17, wherein the active region includes an amorphous indium gallium zinc oxygen semiconductor.

19. The method of claim 17, wherein the lower gate insulating layer includes silicon oxide, and the upper gate insulating layer includes at least one of hafnium oxide, zirconium oxide, aluminum oxide, lanthanum oxide, titanium oxide, tantalum oxide, niobium oxide, or strontium titanium oxide.
